(19) United States
(12) Patent Application Publication
(10) Pub. No.: US 2024/0121947 A1
(43) Pub. Date: Apr. 11, 2024

(54) SEMICONDUCTOR DEVICE

(71) Applicant: SAMSUNG ELECTRONICS CO., LTD., Suwon-si (KR)

(72) Inventors: Eunjung KIM, Suwon-si (KR); Eun A KIM, Suwon-si (KR)

(21) Appl. No.: 18/198,980

(22) Filed: May 18, 2023

(30) Foreign Application Priority Data
Oct. 5, 2022 (KR) 10-2022-0127008

(51) Int. Cl. H10B 12/00

(52) U.S. Cl. CPC H10B 12/482; H10B 12/485; H10B 12/488

(57) ABSTRACT

A semiconductor device includes active patterns disposed on a substrate and including central portions, respectively, bit lines extending in a first direction on the central portions of the active patterns, word lines intersecting the active patterns in a second direction intersecting the first direction, fence patterns disposed between the bit lines adjacent to each other on the word lines, a contact trench region intersecting the active patterns and the word lines in a third direction intersecting the first and second directions, and bit line contacts and filling insulation patterns alternately arranged in the third direction in the contact trench region. The first to third directions are parallel to a bottom surface of the substrate. The filling insulation patterns are disposed between the word lines and the fence patterns, respectively.

### CROSS-REFERENCE TO RELATED APPLICATION

This U.S. non-provisional patent application claims priority under 35 U.S.C. § 119 to Korean Patent Application No. 10-2022-0127008, filed on Oct. 5, 2022, in the Korean Intellectual Property Office, the entire contents of which are hereby incorporated by reference.

### BACKGROUND

### 1. Field

The present disclosure relates to a semiconductor device, and more particularly, to a semiconductor memory device and a method of manufacturing the same.

### 2. Description of the Related Art

Semiconductor devices are widely used in an electronic industry because of their small sizes, multi-functional characteristics, and/or low manufacturing costs. Semiconductor devices may be categorized as any one of semiconductor memory devices for storing logical data, semiconductor logic devices for processing logical data, and hybrid semiconductor devices having both the function of the semiconductor memory devices and the function of the semiconductor logic devices.

High-speed and low-voltage semiconductor devices have been in demand to satisfy characteristics (e.g., high speed and/or low power consumption) of electronic devices including semiconductor devices. Semiconductor devices have been highly integrated to meet these demands. However, difficulty in manufacturing processes for producing a semiconductor device has also increased with the high integration density of semiconductor devices. Thus, techniques for improving productivity of semiconductor devices have been variously studied.

### SUMMARY

In an aspect, a semiconductor device may include active patterns disposed on a substrate and including central portions, respectively, bit lines extending in a first direction on the central portions of the active patterns, word lines intersecting the active patterns in a second direction intersecting the first direction, fence patterns disposed between the bit lines adjacent to each other on the word lines, a contact trench region intersecting the active patterns and the word lines in a third direction intersecting the first and second directions, and bit line contacts and filling insulation patterns alternately arranged in the third direction in the contact trench region. The first to third directions may be parallel to a bottom surface of the substrate. The filling insulation patterns may be disposed between the word lines and the fence patterns, respectively.

In an aspect, a semiconductor device may include an active pattern disposed on a substrate and including a central portion, a bit line extending in a first direction on the central portion of the active pattern, a pair of word lines intersecting the active pattern in a second direction intersecting the first direction with the central portion of the active pattern interposed therebetween, a contact trench region intersecting the active pattern and the word lines in a third direction intersecting the first and second directions, a bit line contact disposed between the central portion of the active pattern and the bit line in the contact trench region, and a pair of filling insulation patterns disposed on the pair of word lines, respectively, in the contact trench region. The first to third directions may be parallel to a bottom surface of the substrate. The bit line contact may cover a portion of a top surface of the central portion of the active pattern, and the pair of filling insulation patterns may cover other portions of the top surface of the central portion of the active pattern.

In an aspect, a semiconductor device may include active patterns disposed on a substrate and including central portions, respectively, bit lines extending in a first direction on the central portions of the active patterns, respectively, word lines intersecting the active patterns in a second direction intersecting the first direction, a contact trench region intersecting the active patterns and the word lines in a third direction intersecting the first and second directions, and bit line contacts and filling insulation patterns alternately arranged in the third direction in the contact trench region. The first to third directions may be parallel to a bottom surface of the substrate. Each of the filling insulation patterns may intersect a corresponding one of the word lines in the third direction.

### BRIEF DESCRIPTION OF THE DRAWINGS

Features will become apparent to those of skill in the art by describing in detail exemplary embodiments with reference to the attached drawings in which:

FIG. 1 is a block diagram illustrating a semiconductor device according to some embodiments.

FIG. 2A is a plan view corresponding to a portion ‘P1’ of FIG. 1 to illustrate a semiconductor device according to some embodiments.

FIG. 2B is an enlarged view of an active pattern of FIG. 2A.

FIGS. 3A to 3C are cross-sectional views taken along lines A-A′, B-B′ and C-C′ of FIG. 2A, respectively.

FIG. 4A is a plan view corresponding to the portion ‘P1’ of FIG. 1 to illustrate a semiconductor device according to some embodiments.

FIG. 4B is an enlarged view of an active pattern of FIG. 4A.

FIGS. 5 and 6 are cross-sectional views taken along a line B-B′ of FIG. 4A.

FIGS. 7 to 16B are views illustrating a method of manufacturing a semiconductor device according to some embodiments.

FIGS. 17 to 24B are views illustrating a method of manufacturing a semiconductor device according to some embodiments.

### DETAILED DESCRIPTION

Example embodiments will now be described more fully with reference to the accompanying drawings.

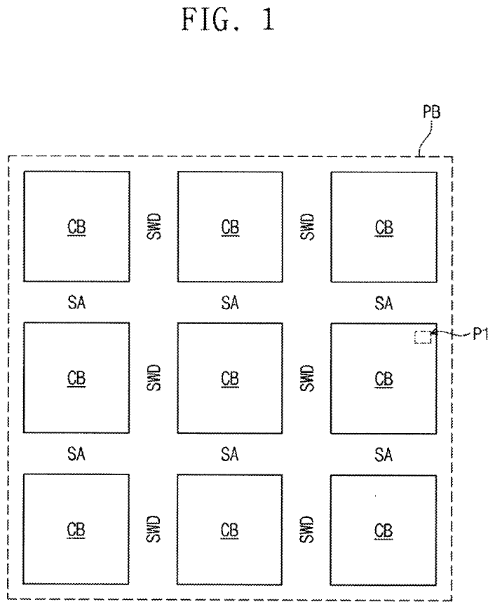

FIG. 1 is a block diagram illustrating a semiconductor device according to some embodiments.

Referring to FIG. 1, a semiconductor device (e.g., a semiconductor memory device) may include cell blocks CB, and a peripheral block PB surrounding each of the cell blocks CB in a plan view. Each of the cell blocks CB may include a cell circuit such as a memory integrated circuit. The peripheral block PB may include various peripheral circuits required for operating the cell circuit, and the peripheral circuits may be electrically connected to the cell circuit.

The peripheral block PB may include sense amplifier circuits SA and sub-word line driver circuits SWD. For example, the sense amplifier circuits SA may face each other with the cell block CB interposed therebetween, and the sub-word line driver circuits SWD may face each other with the cell block CB interposed therebetween. The peripheral block PB may further include power and ground driver circuits for driving the sense amplifier.

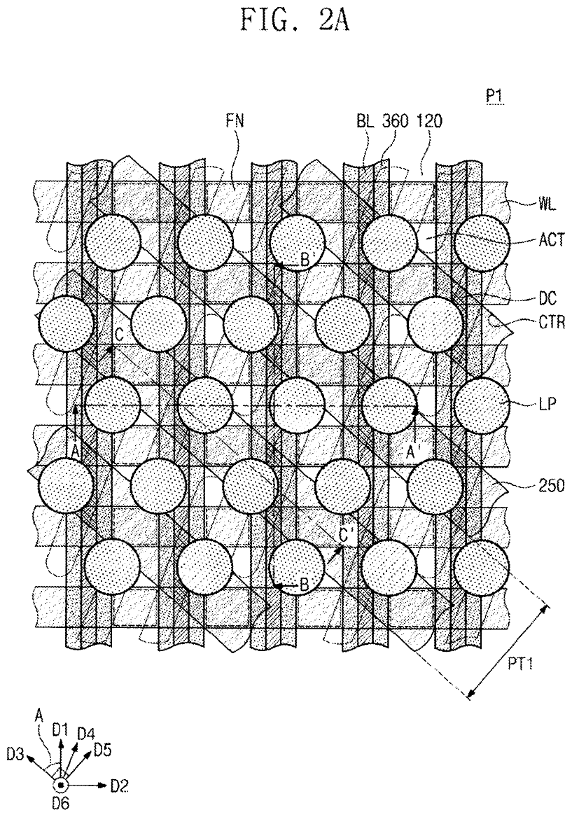

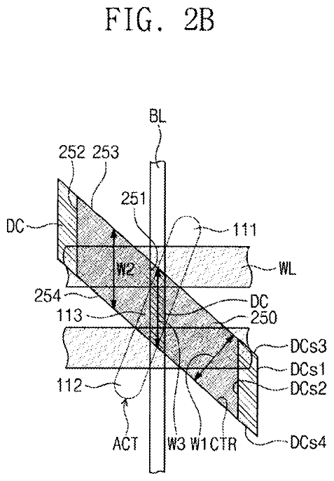

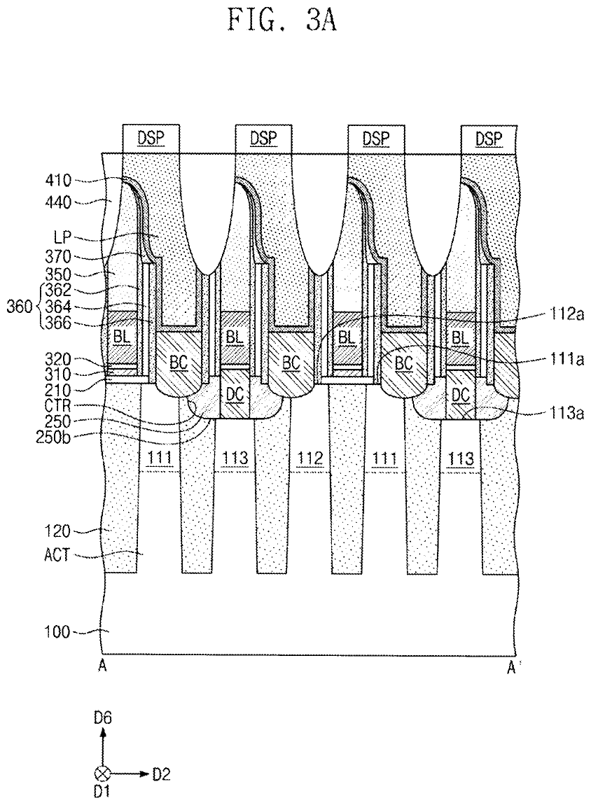

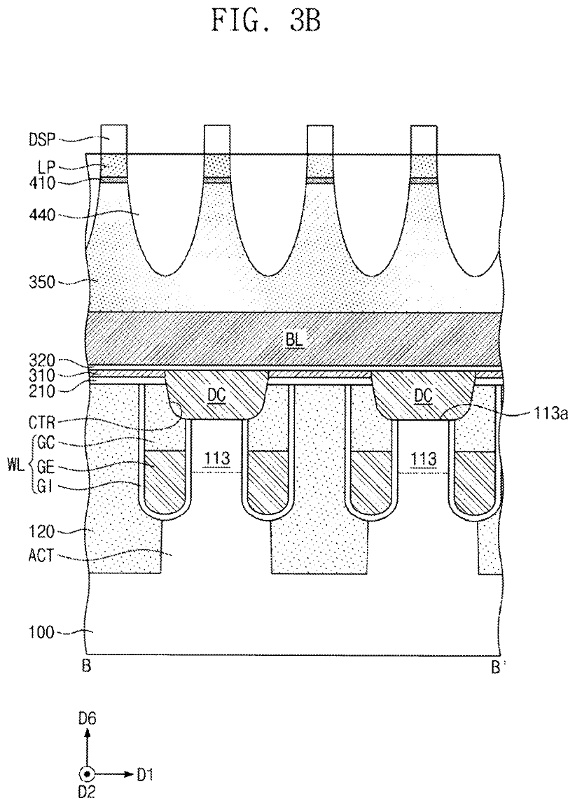

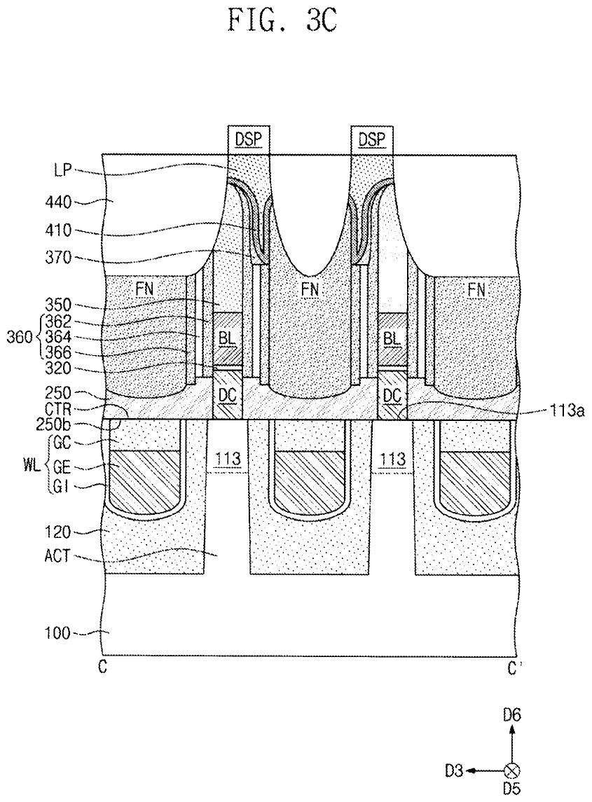

FIG. 2A is a plan view corresponding to a portion ‘P1’ of FIG. 1 to illustrate a semiconductor device according to some embodiments. FIG. 2B is an enlarged view of an active pattern of FIG. 2A. FIGS. 3A to 3C are cross-sectional views taken along lines A-A′, B-B′ and C-C′ of FIG. 2A, respectively.

Referring to FIGS. 2A to 3C, a substrate 100 may be provided. The substrate 100 may be a semiconductor substrate such as a silicon substrate, a germanium substrate, or a silicon-germanium substrate.

A device isolation pattern 120 may be disposed in the substrate 100 and may define active patterns ACT. The active patterns ACT may be spaced apart from each other in a first direction D1 and a second direction D2 which intersect (e.g., are perpendicular to) each other. The first direction D1 and the second direction D2 may be parallel to a bottom surface of the substrate 100.

The active patterns ACT may have island shapes separated from each other. Each of the active patterns ACT may have a bar shape that is long in a fourth direction D4. The fourth direction D4 may be parallel to the bottom surface of the substrate 100 and may intersect the first and second directions D1 and D2. The active patterns ACT may be portions of the substrate 100 that are surrounded by the device isolation pattern 120 when viewed in a plan view. The active patterns ACT may have shapes protruding in a sixth direction D6 perpendicular to the bottom surface of the substrate 100. The device isolation pattern 120 may include an insulating material such as silicon oxide, silicon nitride, or a combination thereof. In the present specification, the term ‘A or B’, ‘at least one of A and B’, ‘at least one of A or B’, ‘A, B or C’, ‘at least one of A, B and C’, or ‘at least one of A, B, or C’ may include any and all combinations of one or more of the associated listed items.

Each of the active patterns ACT may include a pair of edge portions 111 and 112 and a central portion 113. The pair of edge portions 111 and 112 may include a first edge portion 111 and a second edge portion 112. The first edge portion 111 may be an end portion of the active pattern ACT in the fourth direction D4. The second edge portion 112 may be another end portion of the active pattern ACT in the fourth direction D4. The central portion 113 may be a portion of the active pattern ACT disposed between the pair of edge portions 111 and 112 and may be a portion of the active pattern ACT disposed between a pair of word lines WL to be described later. Each of top surfaces 111a and 112a of the edge portions 111 and 112 may be located at a greater height than a top surface 113a of the central portion 113. The edge portions 111 and 112 and the central portion 113 may be doped with dopants (e.g., n-type or p-type dopants).

A word line WL may be provided in the active patterns ACT. The word line WL may be provided in plurality. The word lines WL may extend in the second direction D2 and may be spaced apart from each other in the first direction D1. The word lines WL may be disposed in trenches provided in the active patterns ACT and the device isolation pattern 120. For example, a pair of the word lines WL adjacent to each other in the first direction D1 may intersect each of the active patterns ACT.

Each of the word lines WL may include a gate electrode GE, a gate dielectric pattern GI, and a gate capping pattern GC. The gate electrode GE may penetrate the active patterns ACT and the device isolation pattern 120 in the second direction D2. The gate dielectric pattern GI may be disposed between the gate electrode GE and the active patterns ACT and between the gate electrode GE and the device isolation pattern 120. The gate capping pattern GC may be disposed on the gate electrode GE to cover a top surface of the gate electrode GE.

A contact trench region CTR may intersect the active patterns ACT, the device isolation pattern 120, and the word lines WL (e.g., the gate capping patterns GC of the word lines WL) in a third direction D3. The third direction D3 may be parallel to the bottom surface of the substrate 100 and may intersect the first, second and fourth directions D1, D2 and D4. For example, an angle between the first direction D1 and the third direction D3 may be equal to or greater than 30 degrees and equal to or less than 60 degrees. An inner surface of the contact trench region CTR may expose the top surfaces 113a of the central portions 113 of the active patterns ACT, the device isolation pattern 120, and the word lines WL (e.g., the gate capping patterns GC of the word lines WL).

The contact trench region CTR may be provided in plurality. Each of the contact trench regions CTR may extend in the third direction D3 on the central portions 113 arranged in a line. Here, the central portions 113 arranged in a line may be defined as the central portions 113, sequentially arranged in a line in the third direction D3, among the central portions 113 of the active patterns ACT. The top surfaces 113a of the central portions 113 arranged in a line may be exposed at a bottom of the contact trench region CTR. For example, the top surfaces 113a of the central portions 113 arranged in a line may be completely exposed by the contact trench region CTR. The contact trench region CTR may not expose the top surfaces 111a and 112a of the edge portions 111 and 112 of the active patterns ACT. A width W1 of the contact trench region CTR in a fifth direction D5 may be 30 nm or less. A pitch PT1 of the contact trench regions CTR in the fifth direction D5 may be 80 nm or less. Here, the pitch PT1 may be defined as a minimum distance by which the contact trench regions CTR are repeated in the fifth direction D5.

A buffer pattern 210 may be disposed on the substrate 100. The buffer pattern 210 may cover a portion of the active pattern ACT, a portion of the device isolation pattern 120, and a portion of the word line WL. For example, the buffer pattern 210 may include at least one of silicon oxide, silicon nitride, silicon oxynitride, or any combination thereof.

A bit line BL may be provided on the device isolation pattern 120 and the active patterns ACT. The bit line BL may be provided in plurality. The bit lines BL may extend in the first direction D1 and may be spaced apart from each other in the second direction D2. The bit line BL may include a metal material. For example, each of the bit lines BL may extend in the first direction D1 on the central portions 113 of the active patterns ACT arranged in the first direction D1. For example, the bit line BL may include at least one of tungsten, rubidium, molybdenum, titanium, or any combination thereof.

A bit line contact DC may be provided on each of the active patterns ACT and may be provided in plurality. The bit line contacts DC may be connected onto the central portions 113 of the active patterns ACT, respectively. The bit line contacts DC may be spaced apart from each other in the first and second directions D1 and D2. Each of the bit line contacts DC may be disposed between the central portion 113 of the active pattern ACT and the bit line BL. The bit line contact DC may electrically connect a corresponding one of the bit lines BL to a corresponding one of the central portions 113. The bit line contact DC may include at least one of poly-silicon doped with dopants, undoped poly-silicon, a metal material, or any combination thereof.

The bit line contacts DC arranged in a line may be disposed in the contact trench region CTR and may partially fill the contact trench region CTR. Here, the bit line contacts DC arranged in a line may be defined as the bit line contacts DC, sequentially arranged in a line in the third direction D3, among the bit line contacts DC. The bit line contacts DC arranged in a line may be located on the central portions 113 arranged in a line.

For example, the bit line contact DC may have a parallelogram shape when viewed in a plan view. The bit line contact DC may include first to fourth sides DCs1, DCs2, DCs3 and DCs4. The first side DCs1 and the second side DCs2 of the bit line contact DC may extend in the first direction D1 and may be opposite to each other. The first and second sides DCs1 and DCs2 of the bit line contact DC may be in contact with filling insulation patterns 250 to be described later, respectively. The third side DCs3 and the fourth side DCs4 of the bit line contact DC may extend from the first side DCs1 to the second side DCs2 in the third direction D3 and may be opposite to each other. The third and fourth sides DCs3 and DCs4 of the bit line contact DC may be located on an inner sidewall of the contact trench region CTR.

A filling insulation pattern 250 may be disposed between the bit line contacts DC, adjacent to each other in the third direction D3, of the bit line contacts DC arranged in a line. The filling insulation pattern 250 may be provided in plurality. The filling insulation patterns 250 arranged in a line may be disposed in the contact trench region CTR and may fill the contact trench region CTR along with the bit line contacts DC arranged in a line. Here, the filling insulation patterns 250 arranged in a line may be defined as the filling insulation patterns 250, sequentially arranged in a line in the third direction D3, among the filling insulation patterns 250. In the contact trench region CTR, the bit line contacts DC and the filling insulation patterns 250 may be alternately arranged in the third direction D3. Each of the filling insulation patterns 250 may extend in the third direction D3.

The filling insulation pattern 250 may intersect the word line WL. For example, the filling insulation pattern 250 may intersect the word line WL in the third direction D3. The filling insulation pattern 250 may be in contact with the word line WL (e.g., the gate capping pattern GC of the word line WL).

For example, the filling insulation pattern 250 may have a parallelogram shape when viewed in a plan view. For example, the filling insulation pattern 250 may have a parallelogram shape extending in the third direction D3. The filling insulation pattern 250 may include first to fourth sides 251, 252, 253 and 254. The first side 251 and the second side 252 of the filling insulation pattern 250 may extend in the first direction D1 and may be opposite to each other. The first and second sides 251 and 252 of the filling insulation pattern 250 may be in contact with the bit line contacts DC, respectively. The third side 253 and the fourth side 254 of the filling insulation pattern 250 may extend from the first side 251 to the second side 252 in the third direction D3 and may be opposite to each other. The third and fourth sides 253 and 254 of the filling insulation pattern 250 may be located on the inner sidewall of the contact trench region CTR. For example, the third and fourth sides 253 and 254 of the filling insulation pattern 250 may be aligned with the third and fourth sides DCs3 and DCs4 of the bit line contact DC, respectively. A width W2 of the filling insulation pattern 250 in the first direction D1 may be substantially equal to a width W3 of the bit line contact DC in the first direction D1.

As examples, the bit line contact DC may be located on the central portion 113 of the active pattern ACT, and a pair of the filling insulation patterns 250 may be spaced apart from each other in the third direction D3 with the bit line contact DC interposed therebetween. For example, one of the pair of filling insulation patterns 250 may be in contact with the first side DCs1 of the bit line contact DC, and the other thereof may be in contact with the second side DCs2 of the bit line contact DC. The top surface 113a of the central portion 113 of the active pattern ACT may be covered with the bit line contact DC and the pair of filling insulation patterns 250. For example, the bit line contact DC may cover a portion of the top surface 113a of the central portion 113 of the active pattern ACT, and the pair of filling insulation patterns 250 may cover other portions of the top surface 113a of the central portion 113 of the active pattern ACT. For example, the top surface 113a of the central portion 113 of the active pattern ACT may be completely covered by the bit line contact DC and the pair of filling insulation patterns 250. The pair of filling insulation patterns 250 may be disposed on the pair of word lines WL, respectively.

The filling insulation patterns 250 may not cover the top surfaces 111a and 112a of the edge portions 111 and 112 of the active patterns ACT. For example, the filling insulation patterns 250 may be spaced apart from the edge portions 111 and 112. A bottom surface 250b of the filling insulation pattern 250 may be located at a lower height than the top surfaces 111a and 112a of the edge portions 111 and 112 of the active pattern ACT. The bottom surface 250b of the filling insulation pattern 250 may cover the top surface 113a of the central portion 113 of the active pattern ACT. The filling insulation pattern 250 may be formed of a single layer or two or more layers. For example, the filling insulation pattern 250 may include at least one of silicon nitride, silicon oxide, or a combination thereof.

A poly-silicon pattern 310 may be disposed between the bit line BL and the buffer pattern 210 and between the bit line contacts DC adjacent to each other in the first direction D1. For example, the poly-silicon pattern 310 may be in contact with the adjacent bit line contacts DC. The poly-silicon pattern 310 may be provided in plurality. A top surface of the poly-silicon pattern 310 may be located at substantially the same height as a top surface of the bit line contact DC. The poly-silicon pattern 310 may include poly-silicon.

A first ohmic pattern 320 may be provided between the bit line BL and the bit line contact DC and between the bit line BL and the poly-silicon pattern 310. The first ohmic patterns 320 may extend in the first direction D1 along the bit lines BL and may be spaced apart from each other in the second direction D2. The first ohmic pattern 320 may include a metal silicide. A first barrier pattern may be disposed between the first ohmic pattern 320 and the bit line BL. The first barrier pattern may include a conductive metal nitride such as titanium nitride or tantalum nitride.

A bit line capping pattern 350 may be provided on a top surface of the bit line BL. The bit line capping pattern 350 may be provided in plurality. The bit line capping patterns 350 may extend in the first direction D1 along the bit lines BL and may be spaced apart from each other in the second direction D2. The bit line capping pattern 350 may vertically overlap with the bit line BL. The bit line capping pattern 350 may be formed of a single layer or a plurality of layers. The bit line capping pattern 350 may include silicon nitride.

A bit line spacer 360 may be provided on a sidewall of the bit line BL and a sidewall of the bit line capping pattern 350. The bit line spacer 360 may cover the sidewall of the bit line BL and the sidewall of the bit line capping pattern 350. The bit line spacer 360 may be provided in plurality. For example, the bit line spacers 360 may extend onto upper portions of the first and second sides DCs1 and DCs2 of the bit line contacts DC.

The bit line spacer 360 may include a plurality of spacers. For example, the bit line spacer 360 may include a first spacer 362, a second spacer 364, and a third spacer 366. The third spacer 366 may be provided on the sidewall of the bit line BL and the sidewall of the bit line capping pattern 350. The first spacer 362 may be disposed between the bit line BL and the third spacer 366 and between the bit line capping pattern 350 and the third spacer 366. The second spacer 364 may be disposed between the first spacer 362 and the third spacer 366. For example, each of the first to third spacers 362, 364 and 366 may include at least one of silicon nitride, silicon oxide, silicon oxynitride, or any combination thereof. In some embodiments, the second spacer 364 may include an air gap separating the first and third spacers 362 and 366 from each other.

A capping spacer 370 may be located on the bit line spacer 360. The capping spacer 370 may cover an upper portion of a sidewall of the bit line spacer 360. For example, the capping spacer 370 may include silicon nitride.

A storage node contact BC may be provided between the bit lines BL adjacent to each other. The storage node contact BC may be provided in plurality. The storage node contacts BC may be spaced apart from each other in the first and second directions D1 and D2. The storage node contacts BC adjacent to each other in the second direction D2 may be spaced apart from each other with the bit line BL interposed therebetween. The storage node contacts BC adjacent to each other in the first direction D1 may be spaced apart from each other with a fence pattern FN (to be described later) interposed therebetween. Each of the storage node contacts BC may fill a recess region provided on a corresponding one of the edge portions 111 and 112 of the active patterns ACT and may be connected to the corresponding edge portion 111 or 112. For example, the storage node contact BC may include at least one of poly-silicon doped with dopants, undoped poly-silicon, a metal material, or any combination thereof.

A fence pattern FN may be provided between the bit lines BL adjacent to each other. The fence pattern FN may be provided in plurality. The fence patterns FN may be spaced apart from each other in the first and second directions D1 and D2. The fence patterns FN adjacent to each other in the second direction D2 may be spaced apart from each other with the bit line BL interposed therebetween. The fence patterns FN adjacent to each other in the first direction D1 may be spaced apart from each other with the storage node contact BC interposed therebetween.

The fence pattern FN may be provided on the word line WL. The contact trench region CTR may extend in the third direction D3 between the fence pattern FN and the word line WL. The filling insulation pattern 250 may be disposed between the fence pattern FN and the word line WL. The filling insulation pattern 250 may extend in the third direction D3 between the fence pattern FN and the word line WL. For example, the fence pattern FN may include silicon nitride.

A second barrier pattern 410 may conformally cover the bit line spacer 360, the storage node contact BC and the fence pattern FN. The second barrier pattern 410 may include a conductive metal nitride such as titanium nitride or tantalum nitride. A second ohmic pattern may be disposed between the second barrier pattern 410 and the storage node contact BC. The second ohmic pattern may include a metal silicide.

A landing pad LP may be provided on the storage node contact BC. The landing pad LP may be provided in plurality, and the landing pads LP may be spaced apart from each other in the first and second directions D1 and D2. Each of the landing pads LP may be connected to a corresponding one of the storage node contacts BC. The landing pad LP may cover a top surface of the bit line capping pattern 350. A lower portion of the landing pad LP may vertically overlap with the storage node contact BC. An upper portion of the landing pad LP may be shifted from the lower portion in the second direction D2. The landing pad LP may include a metal material such as tungsten, titanium, or tantalum.

A filling pattern 440 may surround the landing pad LP when viewed in a plan view. The filling pattern 440 may be disposed between the landing pads LP adjacent to each other. The filling pattern 440 may have a mesh shape including holes penetrated by the landing pads LP, when viewed in a plan view. For example, the filling pattern 440 may include at least one of silicon nitride, silicon oxide, silicon oxynitride, or any combination thereof. In some implementations, the filling pattern 440 may include an empty space (i.e., an air gap) including air.

A data storage pattern DSP may be provided on the landing pad LP. The data storage pattern DSP may be provided in plurality, and the data storage patterns DSP may be spaced apart from each other in the first and second directions D1 and D2. Each of the data storage patterns DSP may be connected to a corresponding one of the edge portions 111 and 112 through a corresponding one of the landing pads LP and a corresponding one of the storage node contacts BC.

For some examples, the data storage pattern DSP may be a capacitor including a lower electrode, a dielectric layer and an upper electrode. In this case, the semiconductor device may be a dynamic random access memory (DRAM) device. For certain examples, the data storage pattern DSP may include a magnetic tunnel junction pattern. In this case, the semiconductor device may be a magnetic random access memory (MRAM) device. For certain examples, the data storage pattern DSP may include a phase-change material or a variable resistance material. In this case, the semiconductor device may be a phase-change random access memory (PRAM) device or a resistive random access memory (ReRAM) device. In certain embodiments, the data storage pattern DSP may include at least one of other various structures and/or materials capable of storing data.

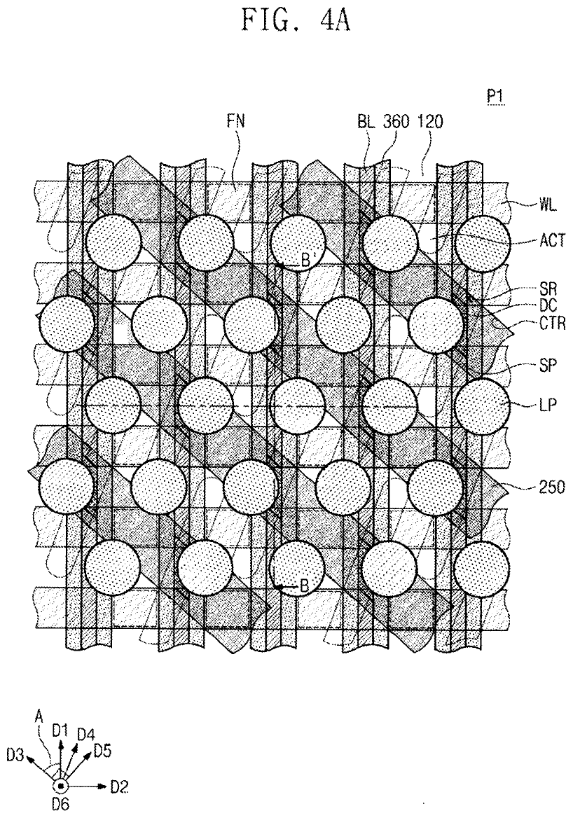

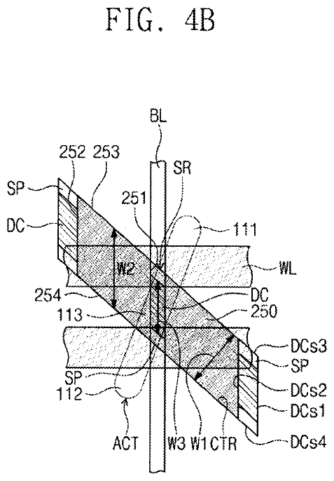

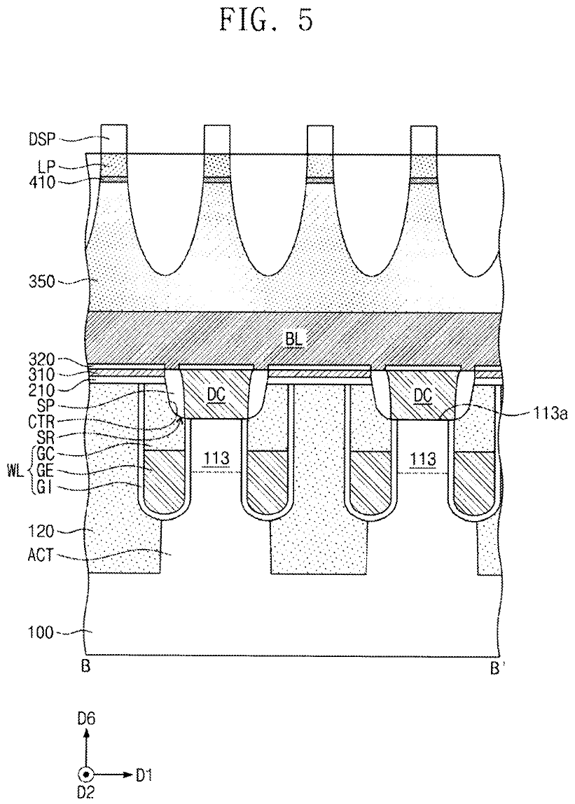

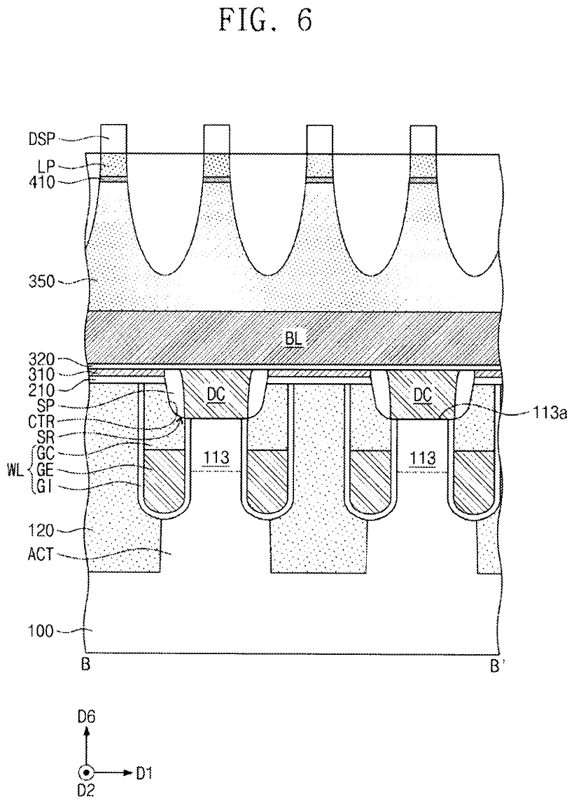

FIG. 4A is a plan view corresponding to the portion ‘P1’ of FIG. 1 to illustrate a semiconductor device according to some embodiments. FIG. 4B is an enlarged view of an active pattern of FIG. 4A. FIGS. 5 and 6 are cross-sectional views taken along a line B-B′ of FIG. 4A. The descriptions of the same features as mentioned above will be omitted for the purpose of ease and convenience in explanation.

Referring to FIGS. 4A to 6, a portion of the contact trench region CTR may be defined as a separation region SR. The separation region SR may be a region of the contact trench region CTR defined between the bit line contact DC and the word line WL under the bit line BL. The separation region SR may be disposed between the bit line contact DC and the poly-silicon pattern 310 and may separate them from each other. A width W3 of the bit line contact DC in the first direction D1 may be less than the width W2 of the filling insulation pattern 250 in the first direction D1.

A separation pattern SP may be provided in the separation region SR. The separation pattern SP may be provided between the bit line contact DC and the word line WL and between the bit line contact DC and the poly-silicon pattern 310. For example, the separation pattern SP may fill the separation region SR. In some implementations, the separation pattern SP may include an empty space (i.e., an air gap) in the separation region SR. The separation pattern SP may include at least one of the same material as the filling insulation pattern 250, the same material (e.g., silicon nitride) as a sacrificial spacer SS to be described later, an air gap, or any combination thereof.

The separation pattern SP may be in contact with the third side DCs3 or the fourth side DCs4 of the bit line contact DC. The separation pattern SP may be in contact with the first side 251 or the second side 252 of the filling insulation pattern 250. A side of the separation pattern SP may extend in the third direction D3 and may be aligned with the third side 253 or the fourth side 254 of the filling insulation pattern 250.

In some embodiments, as shown in FIG. 5, at least a portion of a top surface of the separation pattern SP may not be covered by the first ohmic pattern 320. Thus, a plurality of the first ohmic patterns 320 may be spaced apart from each other in the first direction D1.

In certain embodiments, as shown in FIG. 6, the first ohmic pattern 320 may cover the top surface of the separation pattern SP. The first ohmic pattern 320 may extend onto a top surface of the bit line contact DC and a top surface of the poly-silicon pattern 310.

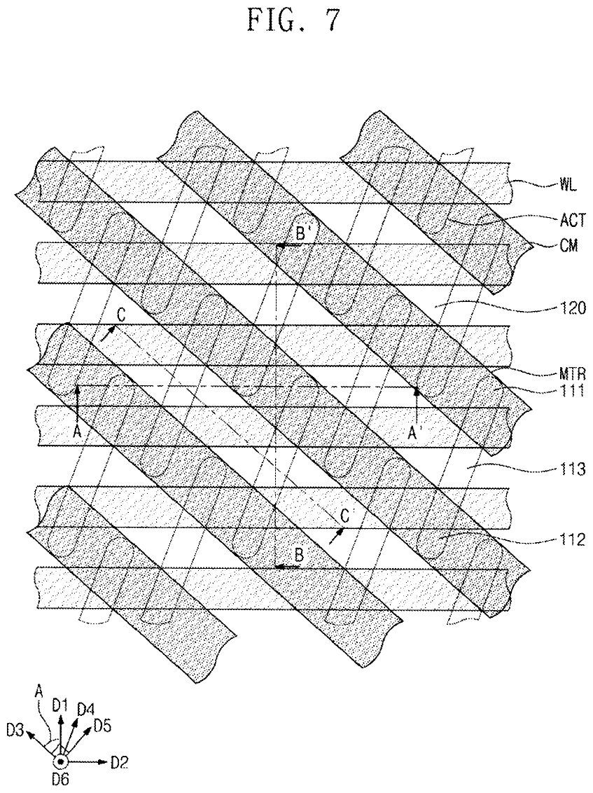

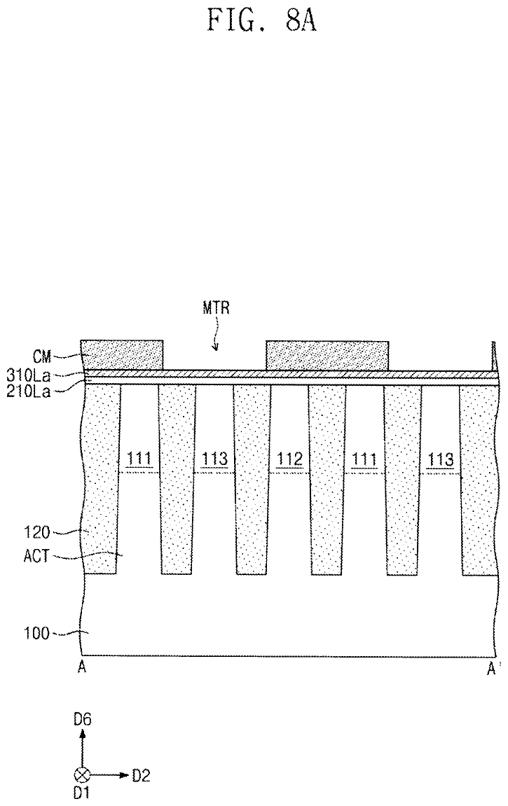

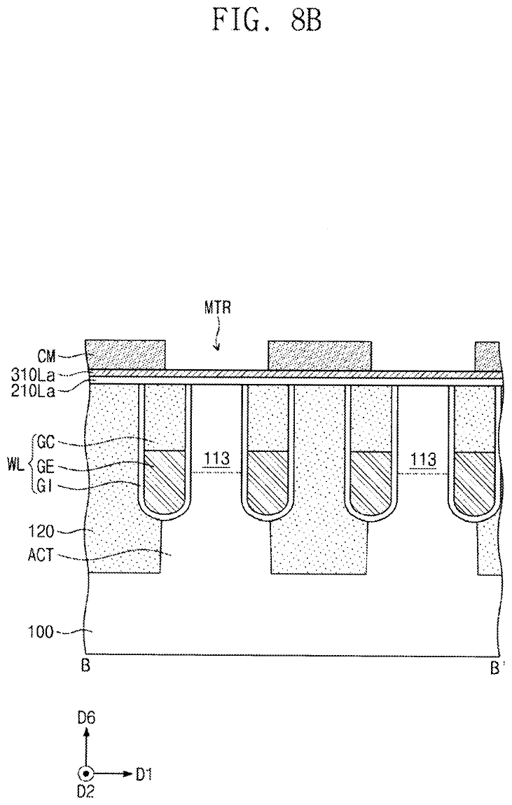

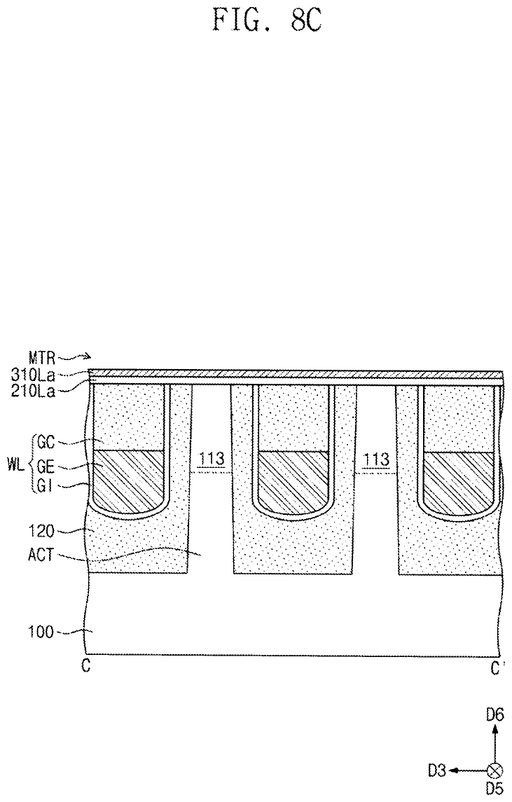

FIGS. 7 to 16B are views illustrating a method of manufacturing a semiconductor device according to some embodiments. More particularly, FIGS. 7, 9, 11, 13 and 15 are plan views corresponding to the portion ‘P1’ of FIG. 1 to illustrate a method of manufacturing a semiconductor device according to some embodiments. FIGS. 8A, 10A, 12A, 14A and 16A are cross-sectional views corresponding to lines A-A′ of FIGS. 7, 9, 11, 13 and 15, respectively. FIGS. 8B, 10B, 12B and 14B are cross-sectional views corresponding to lines B-B′ of FIGS. 7, 9, 11 and 13, respectively. FIGS. 8C, 10C, 12C, 14C and 16B are cross-sectional views corresponding to lines C-C′ of FIGS. 7, 9, 11, 13 and 15, respectively.

Hereinafter, a method of manufacturing the semiconductor device described with reference to FIGS. 2A to 3C will be described with reference to FIGS. 7 to 16B. For the purpose of ease and convenience in explanation, descriptions of the same features as mentioned above will not be repeated.

Referring to FIGS. 7 and 8A to 8C, a device isolation pattern 120 and an active pattern ACT may be formed in a substrate 100. The formation of the device isolation pattern 120 and the active pattern ACT may include forming a groove in the substrate 100 by a patterning process, and forming the device isolation pattern 120 by filling the groove with an insulating material. The active pattern ACT may include a portion of the substrate 100 in which the groove is not formed.

Word lines WL may be formed in trenches formed in an upper portion of the substrate 100. The formation of the word lines WL may include forming mask patterns on the active patterns ACT and the device isolation pattern 120, performing an anisotropic etching process using the mask patterns as etch masks to form the trenches, and filling the trenches with the word lines WL. The word lines WL may be spaced apart from each other in the first direction D1 and may extend in the second direction D2 in the active patterns ACT. For example, the filling of the trenches with the word lines WL may include conformally depositing a gate dielectric pattern GI on an inner surface of each of the trenches, filling the trenches with a conductive layer, forming a gate electrode GE in each of the trenches by performing an etch-back process and/or a polishing process on the conductive layer, and forming a gate capping pattern GC filling a remaining region of each of the trenches on the gate electrode GE. A pair of the word lines WL may intersect the active pattern ACT. A central portion 113 of the active pattern ACT may be defined between the pair of word lines WL. Other portions of the active pattern ACT that are spaced apart from the central portion 113 with the pair of word lines WL interposed therebetween, respectively, may be defined as edge portions 111 and 112.

A first buffer layer 210La and a first poly-silicon layer 310La may be sequentially formed on the substrate 100. The first buffer layer 210La and the first poly-silicon layer 310La may cover a top surface of the active pattern ACT, a top surface of the device isolation pattern 120, and a top surface of the word line WL.

A contact mask pattern CM may be formed on the first poly-silicon layer 310La. The contact mask pattern CM may include a plurality of line patterns extending in the third direction D3 and mask trench regions MTR extending in the third direction D3 between the line patterns. Each of the mask trench regions MTR may extend in the third direction D3 on the central portions 113 arranged in a line.

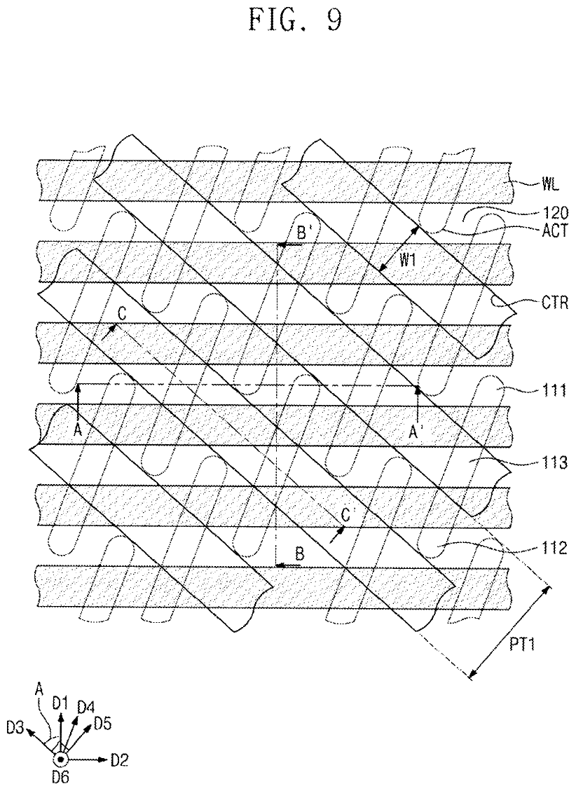

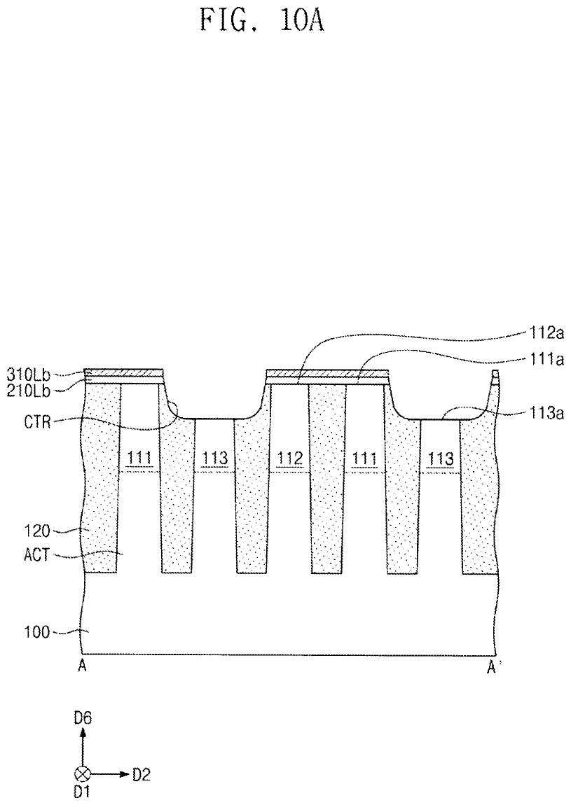

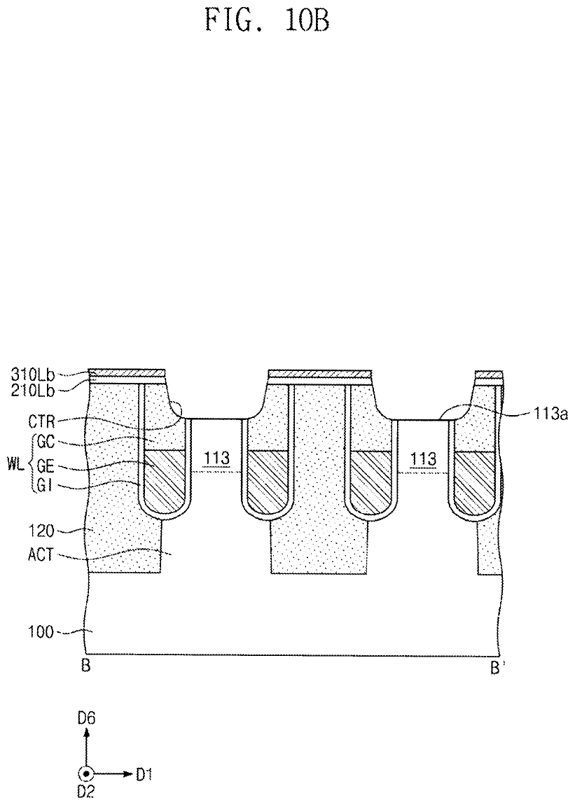

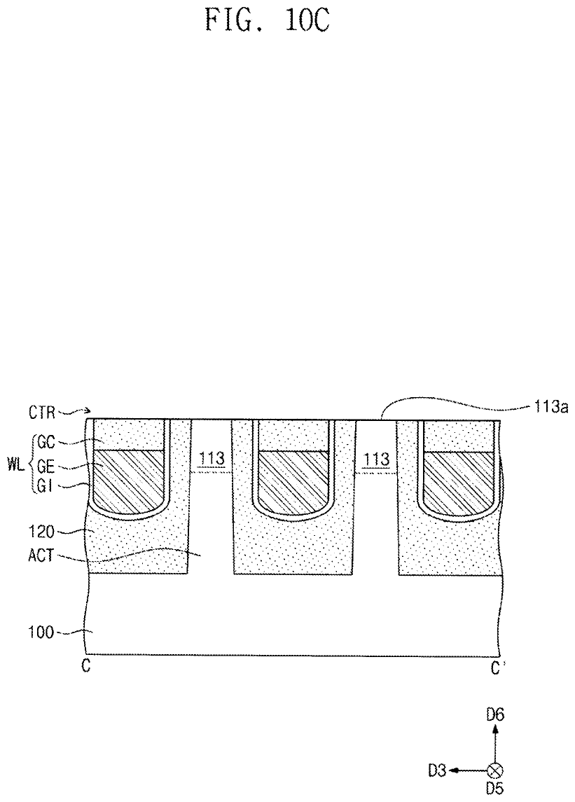

Referring to FIGS. 9 and 10A to 10C, a contact trench region CTR may be formed to intersect the central portions 113 arranged in a line. The formation of the contact trench region CTR may include performing an anisotropic etching process using the contact mask pattern CM as an etch mask. The contact trench region CTR may expose top surfaces 113a of the central portions 113, an upper portion of the word line WL, and an upper portion of the device isolation pattern 120. After the anisotropic etching process, the top surfaces 113a of the central portions 113 may be lowered, and at least a portion of the top surface 113a of the central portion 113 may be exposed by the contact trench region CTR. Top surfaces 11a and 112a of the edge portions 111 and 112 may not be exposed by the contact trench regions CTR. A second buffer layer 210Lb and a second poly-silicon layer 310Lb may be formed from the first buffer layer 210La and the first poly-silicon layer 310La by the anisotropic etching process, respectively.

For example, the formation of the contact trench region CTR may further include performing an isotropic etching process after the anisotropic etching process. A width W1 of the contact trench region CTR in the fifth direction D5 may be further increased by the isotropic etching process. Thus, the top surfaces 113a of the central portions 113 may be completely exposed by the contact trench regions CTR. In some embodiments, the isotropic etching process may not be performed. A pitch PT1 of the contact trench regions CTR in the fifth direction D5 may be 80 nm or less.

When the contact trench regions CTR are formed to have the line shapes as mentioned herein, productivity of a semiconductor device may be improved. More particularly, when performing exposure and etching processes for exposing the central portion 113 of the active pattern ACT of a semiconductor device that is miniaturized, patterning of a line shape extending long in a length direction may be easier than patterning of a dot shape having a narrow area. When contact trench regions CTR having line shapes are formed, the central portions 113 may be effectively exposed. Thus, failure of a semiconductor device may be reduced or minimized. In addition, when a semiconductor device having the same feature size is manufactured, the patterning of the dot shape could require a photo-etch-photo-etch (PEPE) process or an EUV process to expose a central portion of an active pattern. In some implementations, the line shape may be patterned without the above processes. As a result, the productivity of the semiconductor device may be improved.

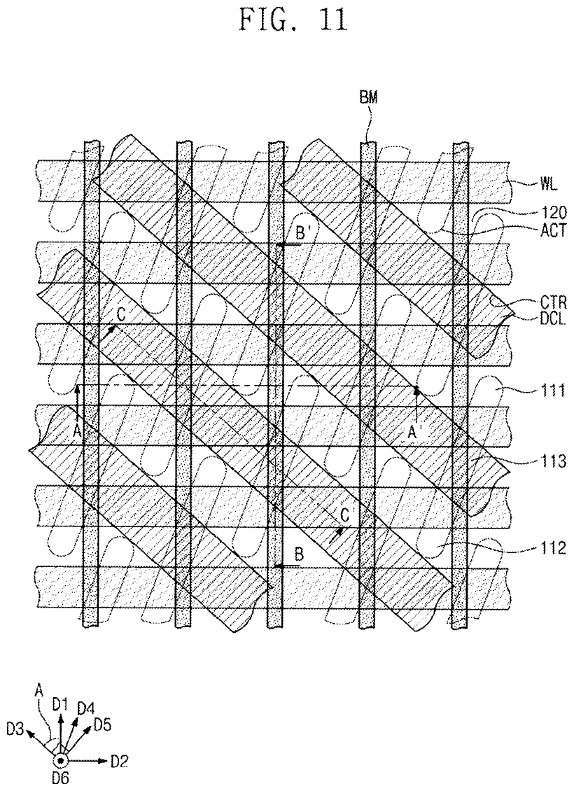

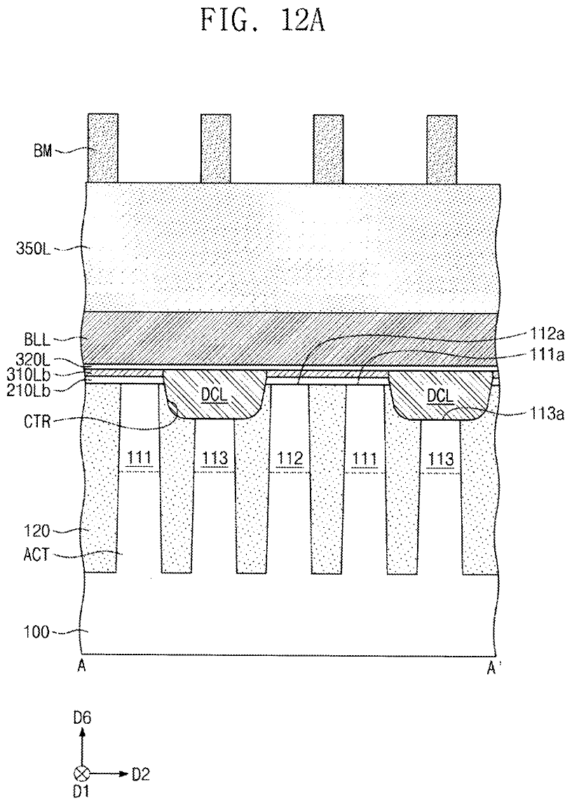

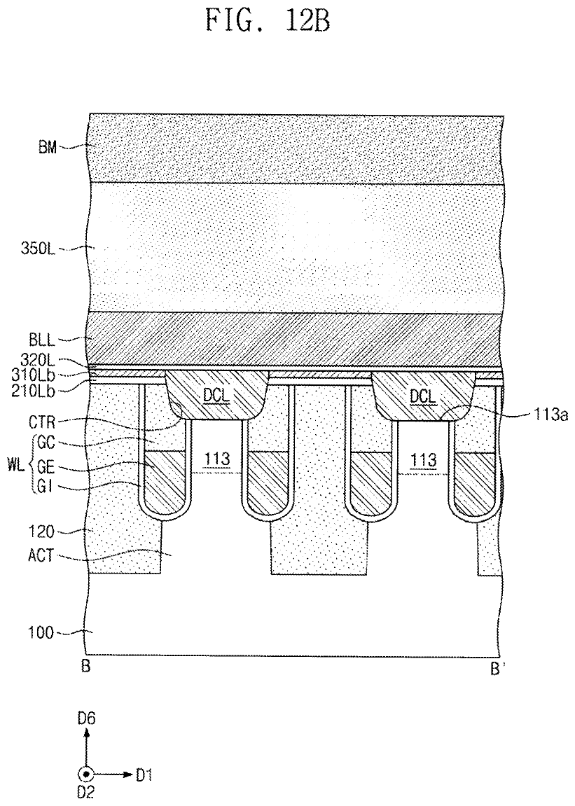

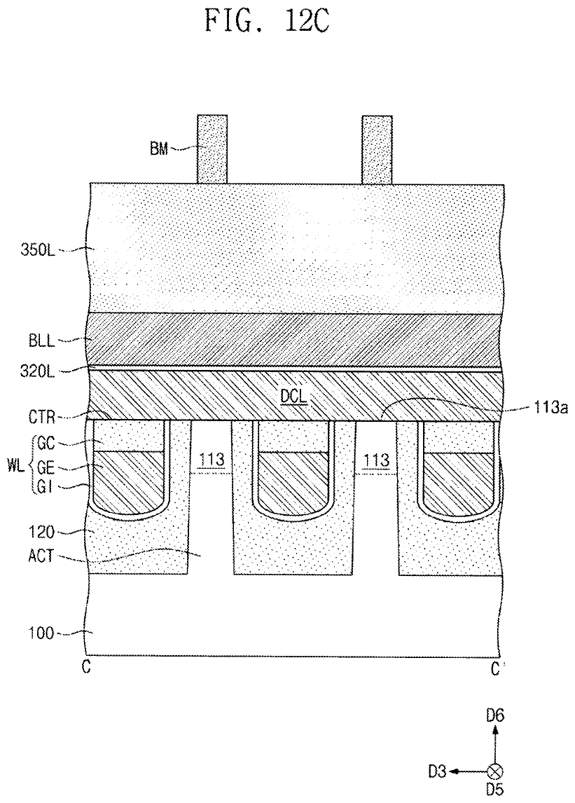

Referring to FIGS. 11 and 12A to 12C, bit line contact lines DCL may be formed to fill the contact trench regions CTR, respectively. The formation of the bit line contact lines DCL may include forming a bit line contact layer covering an entire top surface of the substrate 100 and filling the contact trench regions CTR, and removing an upper portion of the bit line contact layer to expose a top surface of the second poly-silicon layer 310Lb. The upper portion of the bit line contact layer may be removed As a result, the bit line contact layer may be divided into the bit line contact lines DCL.

Thereafter, a bit line layer BLL, a bit line capping layer 350L and a bit line mask pattern BM may be sequentially formed on an entire top surface of the substrate 100. The bit line mask pattern BM may include a plurality of line patterns extending in the first direction D1 and spaced apart from each other in the second direction D2. A first ohmic layer 320L may further be formed between the bit line layer BLL and the bit line contact lines DCL and between the bit line layer BLL and the second poly-silicon layer 310Lb.

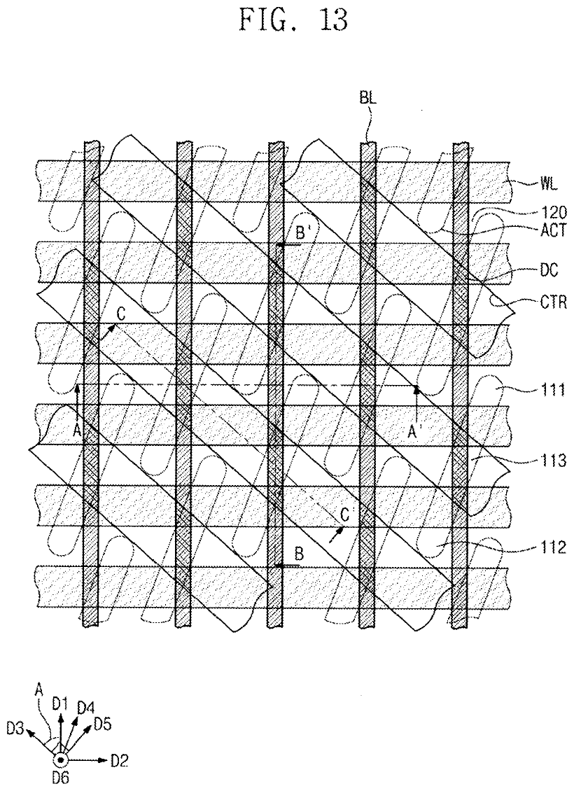

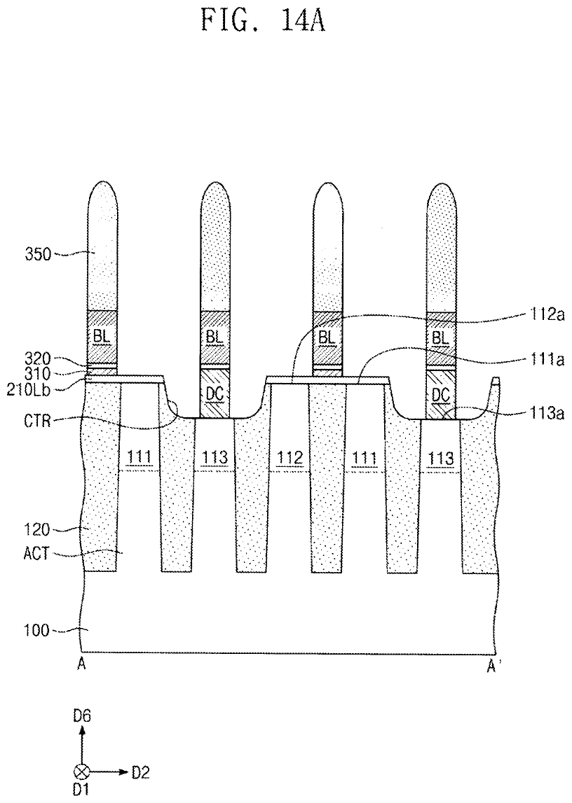

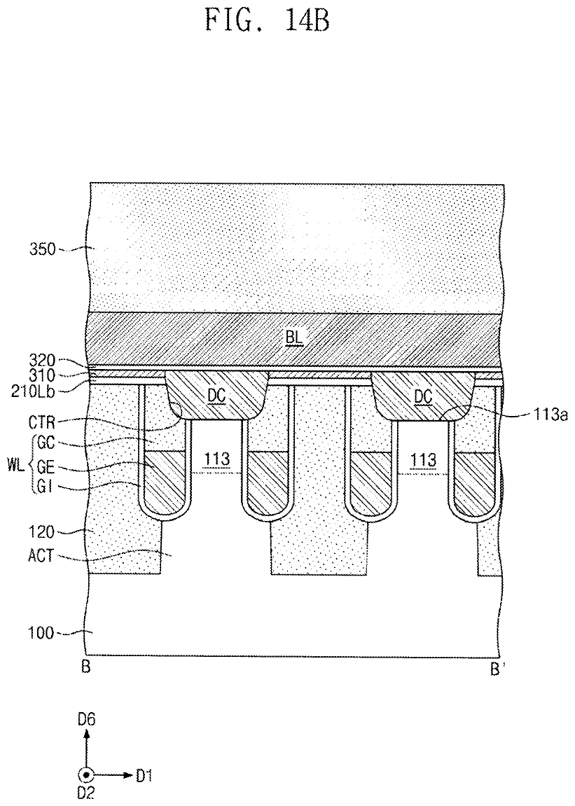

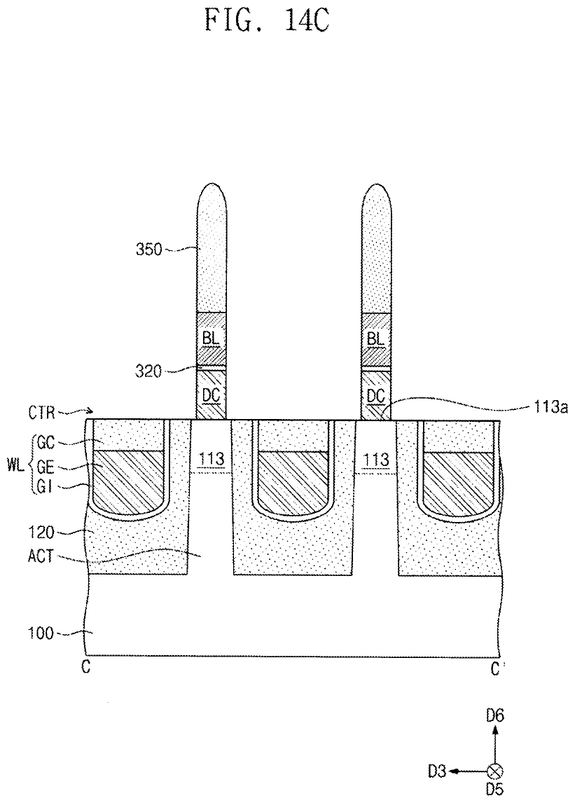

Referring to FIGS. 13 and 14A to 14C, a bit line capping pattern 350, a bit line BL, a first ohmic pattern 320, a bit line contact DC and a poly-silicon pattern 310 may be formed. The bit line capping pattern 350, the bit line BL, the first ohmic pattern 320, the bit line contact DC and the poly-silicon pattern 310 may be formed by etching the bit line capping layer 350L, the bit line layer BLL, the first ohmic layer 320L, the bit line contact line DCL and the second poly-silicon layer 310Lb using the bit line mask pattern BM as an etch mask, respectively.

A portion of the inside of the contact trench region CTR may be exposed again by the etching process. A portion of the top surface 113a of the central portion 113 that is not covered by the bit line contact DC, may be exposed to the outside by the contact trench region CTR. The top surfaces 111a and 112a of the edge portions 111 and 112 may not be exposed by the contact trench regions CTR.

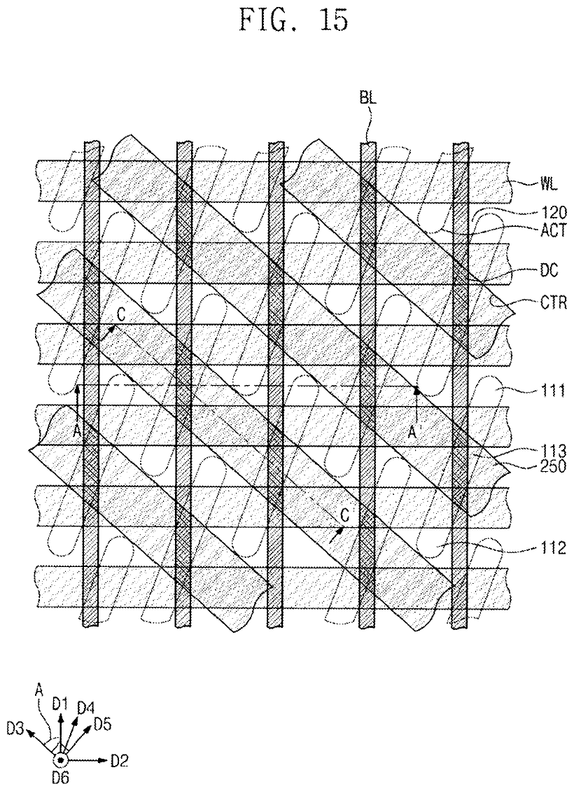

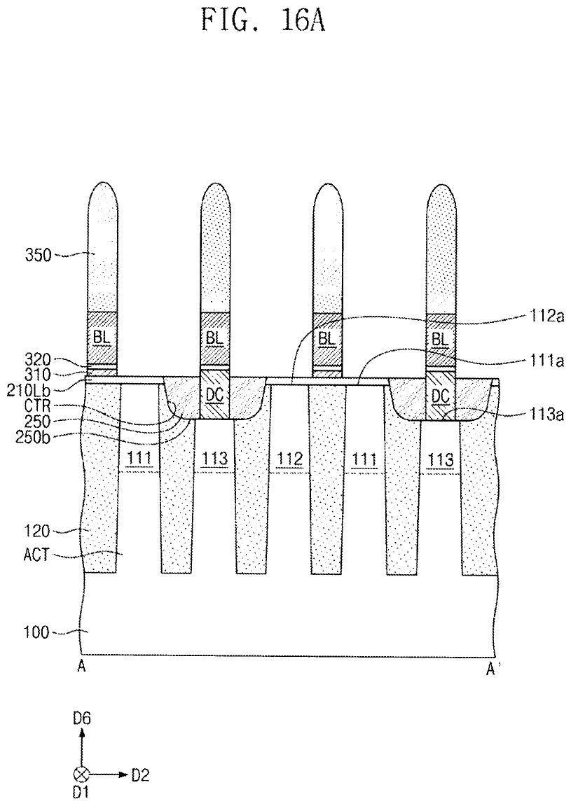

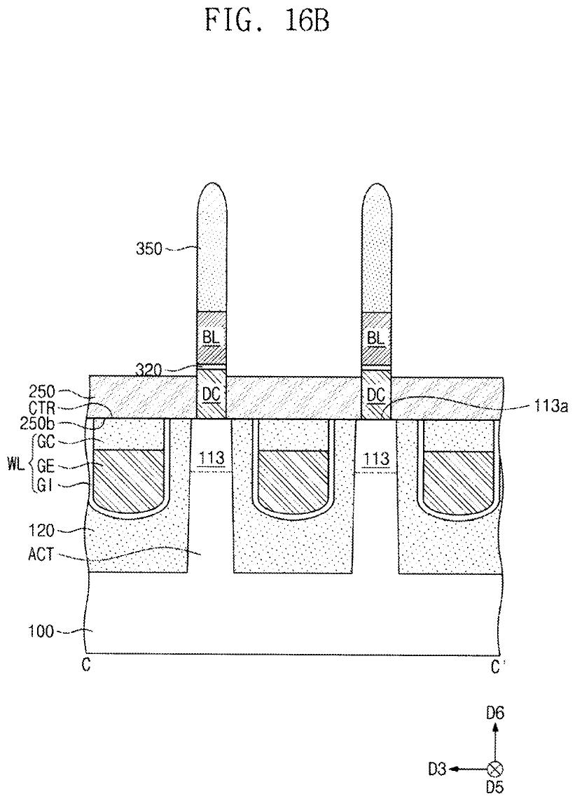

Referring to FIGS. 15, 16A and 16B, filling insulation patterns 250 may be formed to fill the exposed inside of the contact trench region CTR. The formation of the filling insulation patterns 250 may include forming a filling insulation layer, filling the exposed inside of the contact trench region CTR, covering a sidewall of the bit line BL and the second buffer layer 210Lb, and removing the filling insulation layer covering the sidewall of the bit line BL and the second buffer layer 210Lb. For example, filling the insulation layer may conformally cover the sidewall of the bit line BL. Since the filling insulation layer covering the sidewall of the bit line BL and the second buffer layer 210Lb is removed (i.e., an upper portion of the filling insulation layer is removed), the filling insulation layer may be divided into the filling insulation patterns 250.

In some embodiments, the filling insulation pattern 250 may be formed of two or more layers. In this case, filling the insulation layer may include a first filling of the insulation layer and a second filling of the insulation layer. Upper portions of the first and second filled insulation layers may be removed together after the formation of the first and second filled insulation layers, as examples.

Referring again to FIGS. 2A to 3C, a bit line spacer 360 may be formed to cover the sidewall of the bit line BL and a sidewall of the bit line capping pattern 350. The formation of the bit line spacer 360 may include sequentially forming a first spacer 362, a second spacer 364, and a third spacer 366, which conformally cover the sidewall of the bit line BL and the sidewall of the bit line capping pattern 350.

Storage node contacts BC and fence patterns FN may be formed between the bit lines BL adjacent to each other. The storage node contacts BC and the fence patterns FN may be alternately arranged in the second direction D2. Each of the storage node contacts BC may fill a recess region provided on a corresponding one of the edge portions 111 and 112 of the active patterns ACT and may be connected to the corresponding edge portion 111 or 112. The fence patterns FN may be formed on the word lines WL.

In some embodiments, the forming of the storage node contacts BC and the fence patterns FN may include forming storage node contact lines, each of which fills a space between the adjacent bit lines BL and extends in the first direction D1, forming preliminary storage node contacts by removing portions of the storage node contact lines on the word lines WL, forming the fence patterns FN in the removed regions, and forming the storage node contacts BC by removing upper portions of the preliminary storage node contacts. The storage node contact BC may be a lower portion of the preliminary storage node contact, which is not removed.

In some embodiments, the formation of the storage node contacts BC and the fence patterns FN may include forming fence lines each of which fills the space between the adjacent bit lines BL and extends in the first direction D1, forming the fence patterns FN by removing portions of the fence lines on the edge portions 111 and 112 of the active patterns ACT, and forming the storage node contacts BC in the removed regions.

In the process of forming the storage node contacts BC, a portion of an upper portion of the bit line spacer 360 may be removed. Thus, a capping spacer 370 may further be formed at a position from which the portion of the bit line spacer 360 is removed. Thereafter, a second barrier pattern 410 may be formed to conformally cover the bit line spacer 360, the capping spacer 370 and the storage node contacts BC.

Landing pads LP may be formed on the storage node contacts BC. The formation of the landing pads LP may include sequentially forming a landing pad layer) and mask patterns which cover top surfaces of the storage node contacts BC, and dividing the landing pad layer into a plurality of the landing pads LP by an anisotropic etching process using the mask patterns as etch masks. A portion of the second barrier pattern 410, a portion of the bit line spacer 360 and a portion of the bit line capping pattern 350 may be further etched by the anisotropic etching process, and thus may be exposed to the outside.

In some embodiments, the second spacer 364 may be exposed by the anisotropic etching process of the landing pad layer. An etching process may further be performed on the second spacer 364 through the exposed portion of the second spacer 364, such that the second spacer 364 could then include an air gap.

Thereafter, a filling pattern 440 may be formed to cover the exposed portions and to surround each of the landing pads LP in a plan view. A data storage pattern DSP may be formed on each of the landing pads LP.

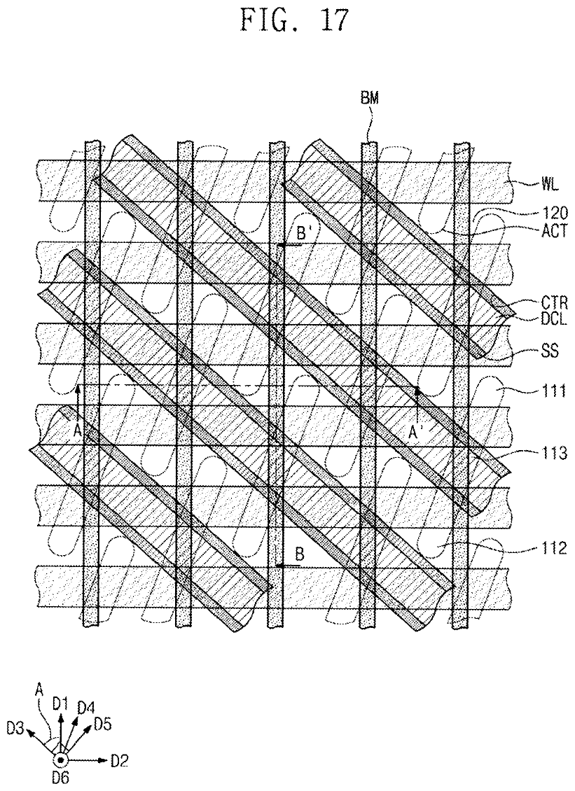

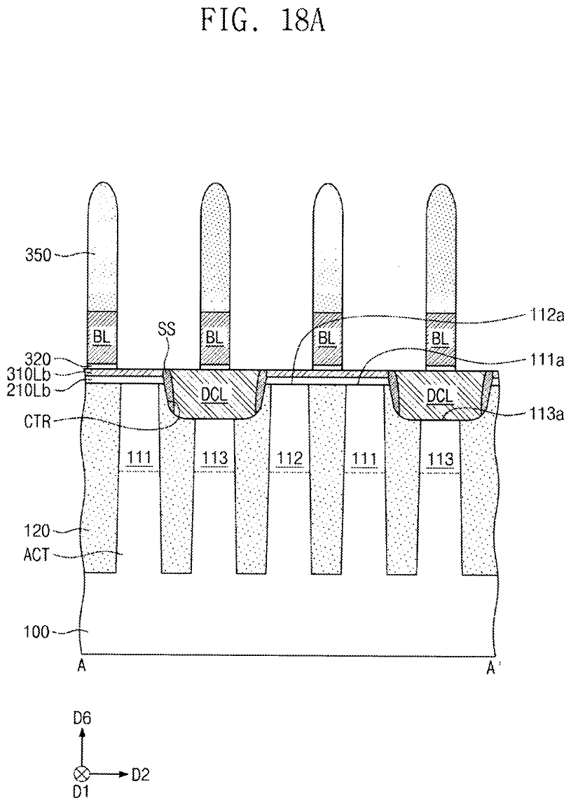

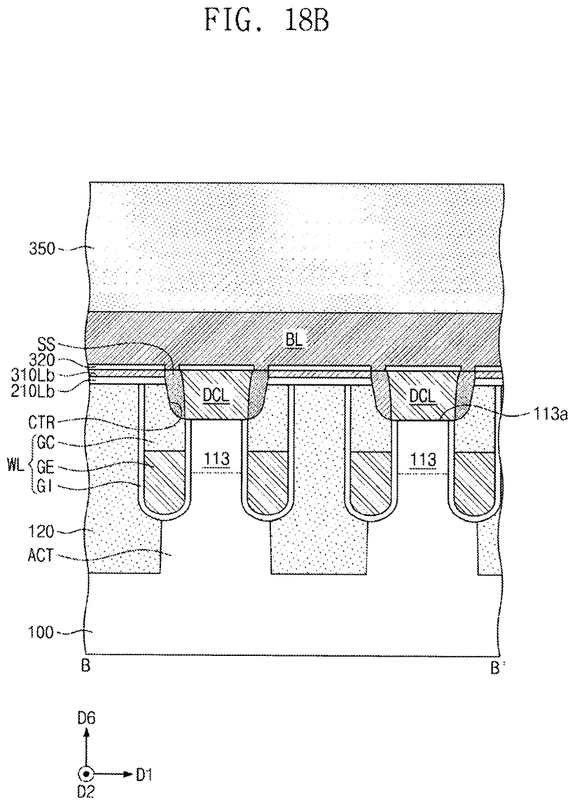

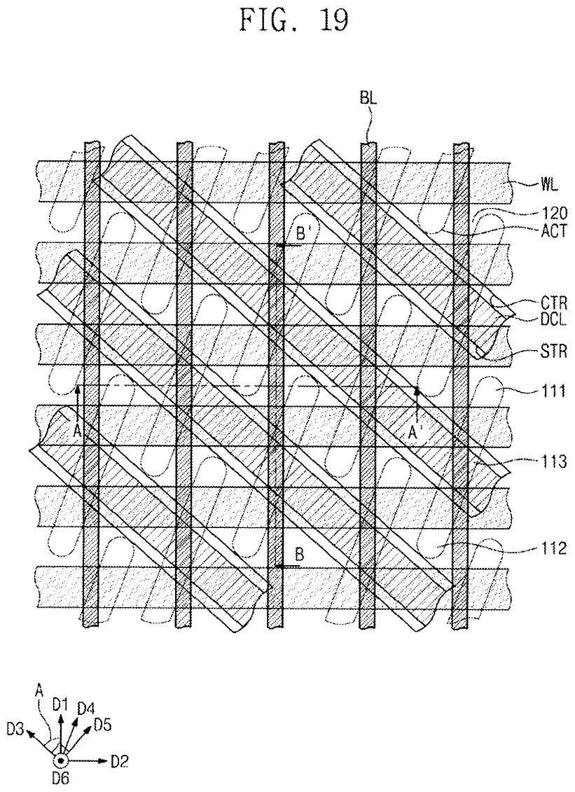

FIGS. 17 to 24B are views illustrating a method of manufacturing a semiconductor device according to some embodiments. More particularly, FIGS. 17, 19, 21 and 23 are plan views corresponding to the portion ‘P1’ of FIG. 1 to illustrate a method of manufacturing a semiconductor device according to some embodiments. FIGS. 18A, 20A, 22A and 24A are cross-sectional views corresponding to lines A-A′ of FIGS. 17, 19, 21 and 23, respectively. FIGS. 18B, 20B, 22B and 24B are cross-sectional views corresponding to lines B-B′ of FIGS. 17, 19, 21 and 23, respectively.

Hereinafter, a method of manufacturing the semiconductor device described with reference to FIGS. 4A to 6 will be described with reference to FIGS. 17 to 24B. The descriptions of the same features as mentioned above will not be repeated, for the purpose of ease and convenience in explanation.

Referring to FIGS. 17, 18A and 18B, after the formation of the contact trench region CTR described with reference to FIGS. 9 to 10C, a sacrificial spacer SS may be formed on an inner sidewall of the contact trench region CTR. The formation of the sacrificial spacer SS may include forming a sacrificial spacer layer conformally covering an inner surface of the contact trench region CTR on an entire top surface of the substrate 100, and dividing the sacrificial spacer layer into the sacrificial spacers SS by removing a portion of the sacrificial spacer layer. Two sacrificial spacers SS may be formed on both inner sidewalls of each of the contact trench regions CTR, respectively. The sacrificial spacer SS may extend in the third direction D3 along the inner sidewall of the contact trench region CTR. The sacrificial spacer SS may include a material having an etch selectivity with respect to the bit line contact DC. For example, the sacrificial spacer SS may include at least one of silicon nitride, silicon oxide, or a combination thereof.

The bit line contact line DCL may be formed to fill a remaining portion of the contact trench region CTR, and the bit line layer BLL, the bit line capping layer 350L and the bit line mask pattern BM of FIGS. 11 to 12C may be sequentially formed. The bit line contact line DCL may be spaced apart from the second poly-silicon layer 310Lb by the sacrificial spacer SS. Thereafter, the bit line capping pattern 350, the bit line BL, and the first ohmic pattern 320 may be formed using an etching process. The etching process may be performed to expose a top surface of the bit line contact line DCL, a top surface of the second poly-silicon layer 310Lb, and a top surface of the sacrificial spacer SS.

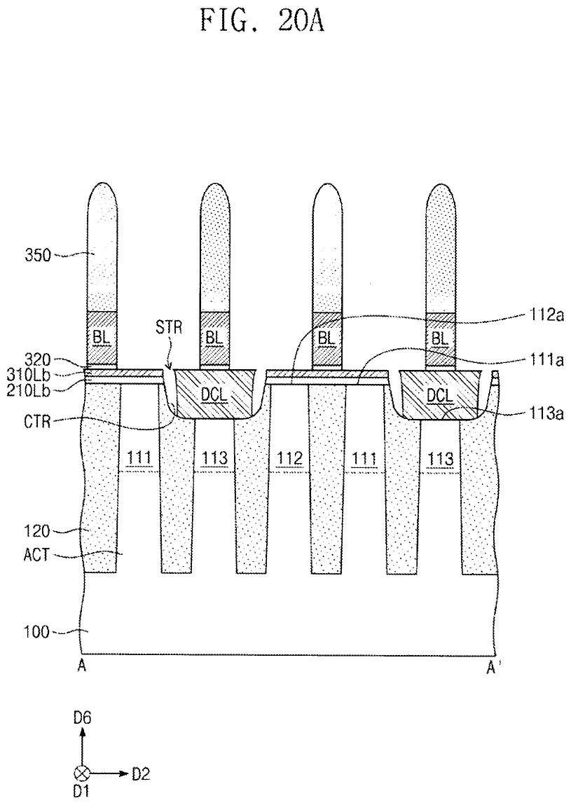

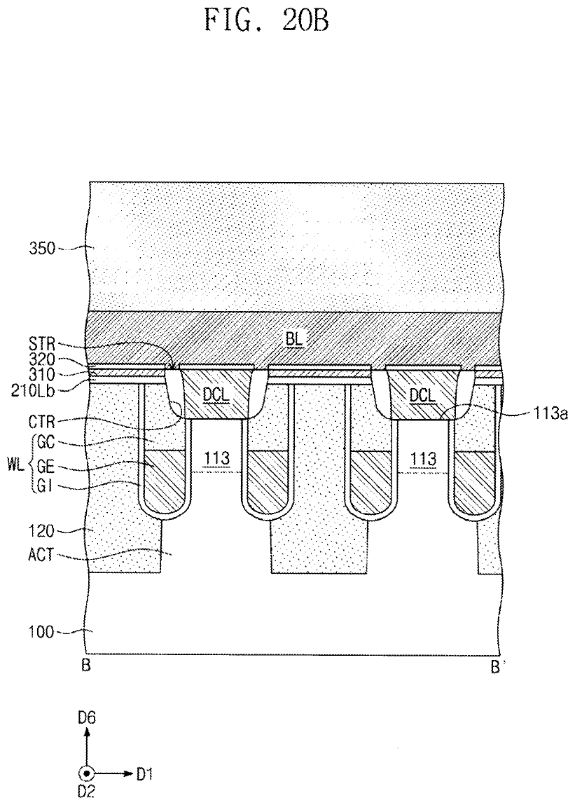

Referring to FIGS. 19, 20A and 20B, the sacrificial spacer SS may be removed. A side trench region STR may be formed in the contact trench region CTR by the removal of the sacrificial spacer SS. The side trench region STR may be a region defined by the inner sidewall of the contact trench region CTR and a sidewall of the bit line contact line DCL and may be formed in a region at which the sacrificial spacer SS had been located. For example, the side trench region STR may extend in the third direction D3. The removal of the sacrificial spacer SS may include performing an isotropic or anisotropic etching process on the sacrificial spacer SS.

In some embodiments, the sacrificial spacer SS may be completely removed by the removal process of the sacrificial spacer SS. In certain embodiments, a portion of the sacrificial spacer SS may be removed by the removal process of the sacrificial spacer SS, and another portion of the sacrificial spacer SS may remain instead of being removed. For example, the other portion of the sacrificial spacer SS may not be removed but may remain under the bit line BL.

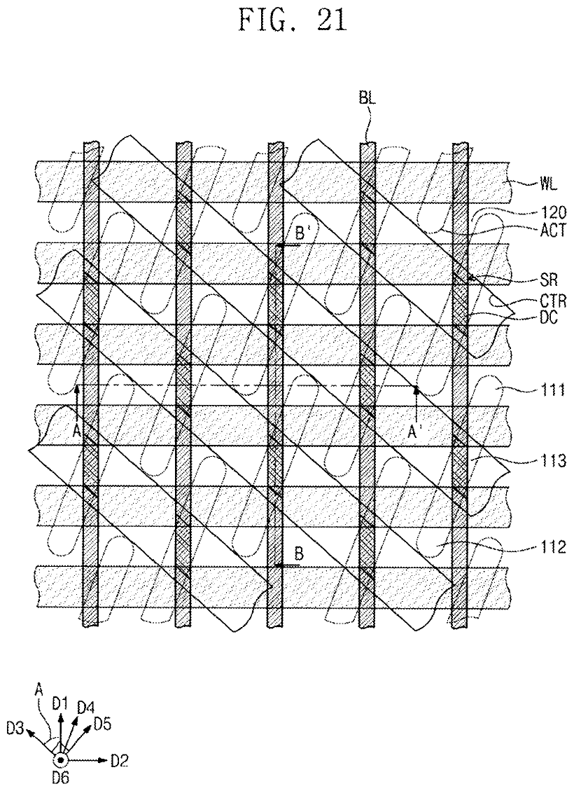

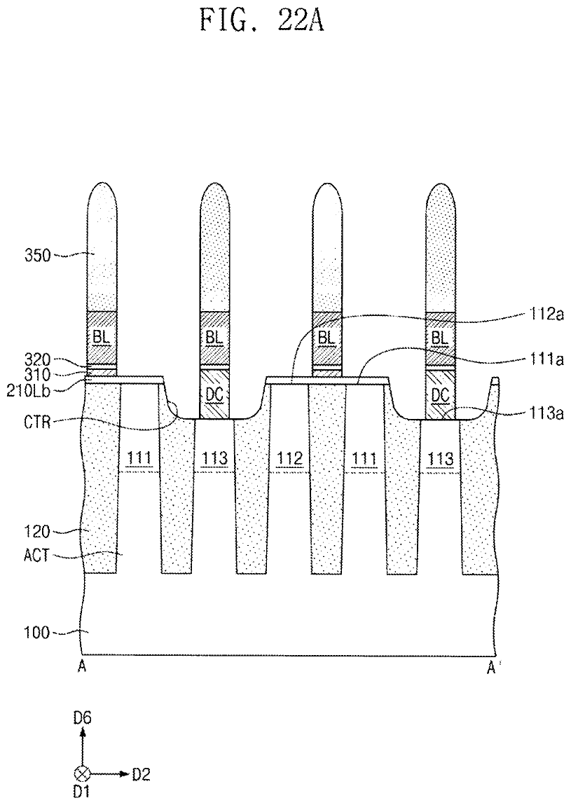

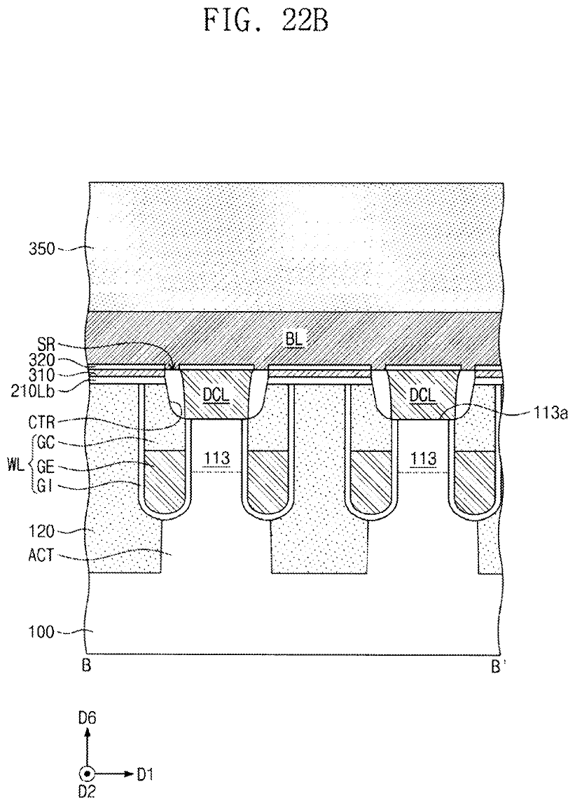

Referring to FIGS. 21, 22A and 22B, the bit line contact DC and the poly-silicon pattern 310 may be formed. The formation of the bit line contact DC may include etching the bit line contact line DCL. At this time, the side trench region STR may be provided as an etching path of the bit line contact line DCL, and thus the bit line contact line DCL may be easily etched. In particular, the bit line contact line DCL may be easily removed in a corner at which the contact trench region CTR forms an acute angle with the bit line BL when viewed in a plan view. As a result, it is possible to prevent an electrical short which could occur if a portion of the bit line contact line DCL were to remain in the corner. Thus, electrical characteristics and reliability of the semiconductor device may be improved.

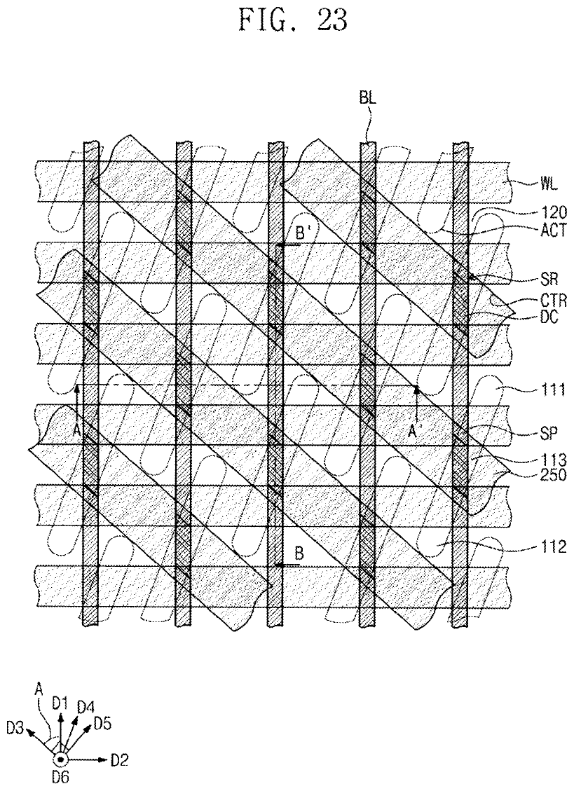

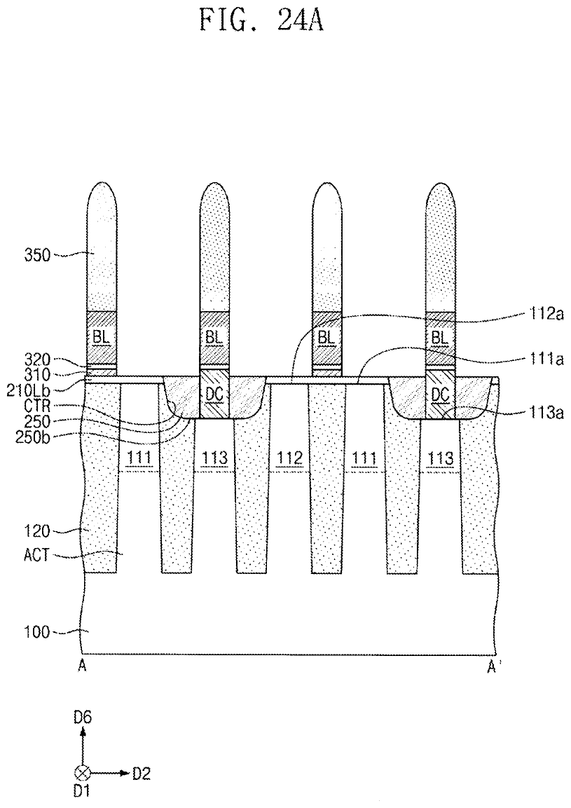

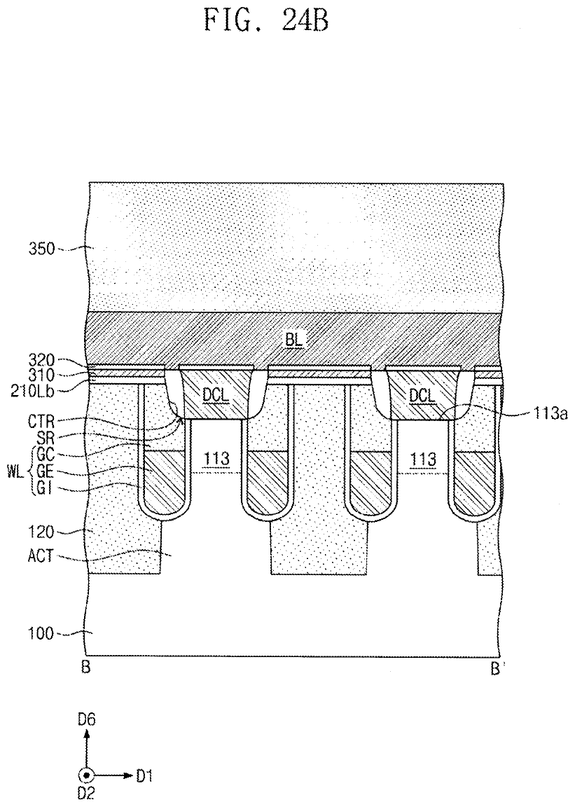

Referring to FIGS. 23, 24A and 24B, the filling insulation pattern 250 filling the contact trench region CTR may be formed. At this time, a region of the contact trench region CTR, which is defined between the bit line contact DC and the word line WL under the bit line BL, may be defined as a separation region SR.

A separation pattern SP may be provided in the separation region SR. In some embodiments, the separation pattern SP may include a remaining portion of the sacrificial spacer SS, which is not removed in the removal process of the sacrificial spacer SS described with reference to FIGS. 19 to 20B. In certain embodiments, the separation pattern SP may be a portion of the filling insulation pattern 250, which is formed in the separation region SR in the formation of the filling insulation pattern 250. In certain embodiments, the separation pattern SP may include an air gap. For example, the air gap may be an empty space surrounded by the filling insulation pattern 250 and/or the sacrificial spacer SS.

According to embodiments, the contact trench region having the line shape may be formed. Thus, process failure may be reduced or minimized in manufacturing the semiconductor device, and the productivity of the semiconductor device may be improved.

In addition, etching may be easily performed in the process of removing the bit line contact line, and thus it is possible to prevent an electrical short which may be caused by a remaining portion of the bit line contact line. As a result, the electrical characteristics and reliability of the semiconductor device may be improved.

By way of summation and review, embodiments may provide a semiconductor device with improved productivity. Embodiments may also provide a semiconductor device with improved electrical characteristics and reliability.

Example embodiments have been disclosed herein, and although specific terms are employed, they are used and are to be interpreted in a generic and descriptive sense only and not for purpose of limitation. Accordingly, it will be understood by those of skill in the art that various changes in form and details may be made without departing from the spirit and scope of the present invention as set forth in the following claims.

What is claimed is:

1. A semiconductor device comprising:
a substrate having active patterns disposed thereon the active patterns including central portions, respectively;
bit lines extending in a first direction on the central portions of the active patterns;
word lines intersecting the active patterns in a second direction intersecting the first direction;
fence patterns disposed between the bit lines adjacent to each other on the word lines;
a contact trench region intersecting the active patterns and the word lines in a third direction intersecting the first and second directions; and
bit line contacts and filling insulation patterns alternately arranged in the third direction in the contact trench region,
wherein the first to third directions are parallel to a bottom surface of the substrate, and
wherein the filling insulation patterns are disposed between the word lines and the fence patterns, respectively.

2. The semiconductor device as claimed in claim 1, wherein the central portions of the active patterns include the central portions arranged in a line along the third direction, and
wherein the contact trench region extends on the central portions arranged in the line.

3. The semiconductor device as claimed in claim 2, wherein each of the bit line contacts covers a portion of each of top surfaces of the central portions arranged in the line, and
wherein the filling insulation patterns cover other portions of each of the top surfaces of the central portions arranged in the line.

4. The semiconductor device as claimed in claim 3, wherein the top surfaces of the central portions arranged in the line are completely covered by the bit line contacts and the filling insulation patterns.

5. The semiconductor device as claimed in claim 1, wherein each of the filling insulation patterns intersects a corresponding one of the word lines in the third direction.

6. The semiconductor device as claimed in claim 1, wherein each of the filling insulation patterns includes a first side being in contact with the bit line contact, a second side opposite to the first side, a third side extending from the first side to the second side, and a fourth side opposite to the third side.

7. The semiconductor device as claimed in claim 6, wherein each of the bit line contacts includes a side extending in the third direction, and
wherein the sides of the bit line contacts are aligned with the third sides of the filling insulation patterns.

8. The semiconductor device as claimed in claim 1, wherein each of the word lines comprises: a gate electrode extending in the second direction; and a gate capping pattern on the gate electrode, and
wherein each of the filling insulation patterns is in contact with the gate capping pattern.

9. The semiconductor device as claimed in claim 1, further comprising:
separation patterns disposed between the bit line contacts and the word lines.

10. The semiconductor device as claimed in claim 9, further comprising:
poly-silicon patterns extending in the first direction between the bit lines and the word lines,
wherein the separation patterns are disposed between the bit line contacts and the poly-silicon patterns.

11. The semiconductor device as claimed in claim 9, wherein the separation patterns include silicon nitride, the same material as the filling insulation patterns, an air gap, or any combination thereof.

12. The semiconductor device as claimed in claim 1, wherein a width of each of the filling insulation patterns in the first direction is equal to or greater than a width of each of the bit line contacts in the first direction.

13. A semiconductor device comprising:
an active pattern disposed on a substrate and including a central portion;
a bit line extending in a first direction on the central portion of the active pattern;
a pair of word lines intersecting the active pattern in a second direction intersecting the first direction with the central portion of the active pattern interposed therebetween;
a contact trench region intersecting the active pattern and the word lines in a third direction intersecting the first and second directions;
a bit line contact disposed between the central portion of the active pattern and the bit line in the contact trench region; and
a pair of filling insulation patterns disposed on the pair of word lines, respectively, in the contact trench region,
wherein the first to third directions are parallel to a bottom surface of the substrate,
wherein the bit line contact covers a portion of a top surface of the central portion of the active pattern, and
wherein the pair of filling insulation patterns covers other portions of the top surface of the central portion of the active pattern.

14. The semiconductor device as claimed in claim 13, wherein the active pattern includes edge portions spaced apart from each other with the central portion interposed therebetween, and
wherein the bit line contact and the pair of filling insulation patterns do not cover the edge portions of the active pattern.

15. The semiconductor device as claimed in claim 13, wherein the top surface of the central portion of the active pattern is completely covered by the bit line contact and the pair of filling insulation patterns.

16. The semiconductor device as claimed in claim 13, further comprising:
separation patterns disposed between the bit line contact and the pair of word lines, respectively.

17. The semiconductor device as claimed in claim 13, wherein the active pattern includes edge portions spaced apart from each other with the central portion interposed therebetween, and
wherein a bottom surface of each of the pair of filling insulation patterns is located at a lower height than a top surface of each of the edge portions of the active pattern.

18. The semiconductor device as claimed in claim 13, wherein the active pattern includes a plurality of active patterns,
wherein the central portions of the active patterns are arranged in a line along the third direction, and
wherein the contact trench region extends on the central portions arranged in the line.

19. A semiconductor device comprising:
active patterns disposed on a substrate and including central portions, respectively;
bit lines extending in a first direction on the central portions of the active patterns, respectively;
word lines intersecting the active patterns in a second direction intersecting the first direction;
contact trench regions intersecting the active patterns and the word lines in a third direction intersecting the first and second directions; and
bit line contacts and filling insulation patterns alternately arranged in the third direction in each of the contact trench region,
wherein the first to third directions are parallel to a bottom surface of the substrate, and
wherein each of the filling insulation patterns intersects a corresponding one of the word lines in the third direction.

20. The semiconductor device as claimed in claim 19, wherein each of the filling insulation patterns has a parallelogram shape.
